(19) United States
(12) Patent Application Publication
(10) Pub. No.: US 2025/0344492 A1
(43) Pub. Date: Nov. 6, 2025

(54) SEMICONDUCTOR DEVICE WITH FIRST TYPE AND SECOND TYPE UNIT CELLS

(71) Applicant: Huawei Digital Power Technologies Co., Ltd., Shenzhen (CN)

(72) Inventor: Samir Mouhoubi, Nuremberg (DE)

(73) Assignee: Huawei Digital Power Technologies Co., Ltd., Shenzhen (CN)

(21) Appl. No.: 19/270,741

(22) Filed: Jul. 16, 2025

Related U.S. Application Data
(63) Continuation of application No. PCT/EP2023/066592, filed on Jun. 20, 2023.

(51) Int. Cl. H10D 84/80; H10D 62/85; H10D 64/00; H10D 84/01

(52) U.S. Cl. CPC H10D 84/811; H10D 62/8503; H10D 64/111; H10D 84/0109

(57) ABSTRACT

A semiconductor device including: a plurality of unit cells arranged side-by-side across a top surface of the semiconductor device, and where the plurality of unit cells are of a first type or a second type, each unit cell of the first type includes a first electrode, a second electrode, and a third electrode formed at the top surface of the semiconductor device. The second electrode is arranged to enclose the first electrode. Each of the first and second electrodes are arranged to enclose the third electrode. The unit cells of the first type form high electron mobility transistor (HEMT) cells, and the unit cells of the second type form Schottky Barrier Diode (SBD) cells.

### CROSS-REFERENCE TO RELATED APPLICATIONS

This application is a continuation of International Application No. PCT/EP2023/066592, filed on Jun. 20, 2023, the disclosure of which is hereby incorporated by reference in its entirety.

### FIELD

The present disclosure relates to the field of Semiconductor Technology for power device applications, for example wide bandgap power devices. The present disclosure also relates to a semiconductor device with first type and second type unit cells, the first type unit cells forming High Electron Mobility Transistors (HEMTs) and the second type unit cells forming Schottky Barrier Diode (SBD) cells, and a method for manufacturing such a semiconductor device. A hexagonal lateral GaN (Gallium Nitride)-eHEMT (enhanced HEMT) with distributed monolithically integrated SBD is also described in the present disclosure.

### BACKGROUND

Many electronic systems and applications rely on power switching circuits that require power devices to operate in two modes: 1) On-state mode: The power device is in forward mode allowing the conduction of current; 2) Off-state mode: The power device is blocking the conduction of current and sustaining a high voltage. The switching between these two modes forces the power device to operate for very short times, i.e., at each switching event, in a so-called reverse mode or third quadrant: in this configuration, the polarity of the device is inverted and a reverse current needs to be evacuated. In established technologies (like Silicon), the switching device, for example a power metal-oxide semiconductor field-effect transistor (MOSFET), contains inherently a body diode that is used to assist the evacuation of this reverse current.

Gallium Nitride (GaN) is a new emerging technology that exhibits promising potential to replace Silicon in power applications where fast switching and high power is needed. The value of GaN resides in its wide bandgap which is ˜3.4 eV compared to ˜1.1 eV for Silicon. However, many challenges face the deployment of GaN regarding reverse mode conduction: GaN HEMT devices suffer from the following weaknesses: they do not contain a body diode like Silicon based devices. The reverse conduction depends on the threshold voltage in reverse conduction (Vrc) value; which depends in turn on its forward threshold voltage (Vth). It is technologically difficult to tune both of them independently and therefore a compromise is needed. In the current status of the technology, Vth stability is not guaranteed as dynamic Vth shifts can occur. Therefore, it can be challenging to control reverse conduction mode and associated losses accurately.

### SUMMARY

The present disclosure provides a solution for overcoming the limitations of the GaN technology with respect to reverse conduction and stability as described above.

The present disclosure provides a solution for solving the weaknesses of the GaN HEMT device related to reverse conduction.

Embodiments of the present disclosure describe a solution for improving reverse conduction of the GaN HEMT by monolithically integrating a distributed SBD to limit the losses during the switching event.

The present disclosure provides a solution for the above described weakness of the GaN HEMT device/technology in the third quadrant of the Ids/Vds diagram, e.g., during reverse conduction mode. Embodiments of the present disclosure include a novel implementation that is based on a monolithic integration concept as described below.

Embodiments of the present disclosure optimize the integration of the SBD in a distributed way in order to avoid non uniformities in the power device protection. A new concept is implemented where the power device is formed with unit cells that have a closed shape (and not stripe-like shapes). In this way, it is possible to uniformly integrate closed shapes that contain SBD devices instead of GaN-HEMTs.

In accordance with at least one embodiment of the present disclosure, a novel semiconductor device, such as a wide bandgap power device such as GaN-HEMT device, is presented that provides reduced constraints caused by a small pitch on the metallization, improved area/cost, reduced parasitics, and compliance with advanced and efficient packaging schemes.

The novel semiconductor device described herein is based on a unit cell configuration, e.g., of a closed geometrical contour such as, for example, a hexagonal shape, with a full layout and metallization scheme suitable for bond on active packaging.

In the present disclosure, semiconductor devices, in particular HEMT devices and GaN-HEMT devices are described. A high-electron-mobility transistor (HEMT) is a field-effect transistor incorporating a junction between two materials with different band gaps, e.g., a heterojunction as the channel instead of a doped region (as is generally the case for a MOSFET). Commonly used material combinations are Gallium Arsenic (GaAs), Aluminum Gallium Arsenic (AlGaAs), Indium Gallium Arsenic (InGaAs) and GaN. GaN HEMTs are particularly suitable due to their high-power performance. They can be used in a wide range of applications, such as power supplies, DC-to-DC converters, motor controllers, and many other applications.

The novel semiconductor device introduced in the present disclosure can be produced by using a variety of technologies. This can be for example: Gallium Nitride-on-Silicon (GaN-on-Si), Gallium Nitride-on-Gallium Nitride (GaN-on-GaN), Gallium Nitride-on-Silicon Carbide (GaN-on-SiC), Gallium Nitride-on-Silicon-on-Insulator (GaN-on-SOI), Gallium Nitride-on-Qromis Substrate Technology (GaN-on-QST), etc.

The solutions presented hereinafter are applicable to any power conversion system or architecture using semiconductor power devices. The solutions of the present disclosure are applicable when high blocking voltage, high current density, and high switching frequency are required. The solutions of the present disclosure are applicable, as an example, in inductively switching circuits, where there is a need of current freewheeling, e.g., reverse conduction mode, during turn-off of a power semiconductor device. The solutions of the present disclosure are applicable to all power electronic systems targeting energy loss, application size, and total application cost reduction.

Embodiments of the present disclosure can be applied in all power electronics products, such as DC and AC converters used in photovoltaics, electric vehicles, chargers and on-board chargers, data centers, railway, telecom, servers and others.

In order to describe the present disclosure in detail, the following terms and notations will be used:
MOS Metal Oxide Semiconductor;
FET Field Effect Transistor;
MOSFET Metal Oxide Semiconductor Field Effect Transistor;
HEMT High Electron Mobility Transistor;
SiC Silicon Carbide;
GaN Gallium Nitride;
JFET Junction Field Effect Transistor;
SBD Schottky Barrier Diode;
2DEG Two Dimensional Electron Gas;
Vth Threshold voltage;
Vrc Threshold voltage in Reverse conduction;
Ron On-state resistance;
HV High Voltage;
MV Medium Voltage; and
WBG Wide BandGap.

On-state mode: Electrical state in which the power device is in forward mode (allowing the conduction of current).

Off-state mode: Electrical state in which the power device is blocking the conduction of current and sustaining a high voltage.

Switching event: Lapse of time during which the power device changes its electrical state.

Band gap: Energy domain in which no electronic states exist (energy space between the top of the valence band and the bottom of the conduction band).

Wide bandgap: Bandgap larger than 2 eV.

According to a first aspect, the present disclosure includes a semiconductor device, comprising: a plurality of unit cells arranged side-by-side across a top surface of the semiconductor device, wherein the plurality of unit cells are of a first type or a second type, each unit cell of the first type comprises a first electrode, a second electrode and a third electrode formed at the top surface of the semiconductor device; wherein the second electrode is arranged to enclose the first electrode; wherein each of the first and second electrodes is arranged to enclose the third electrode; wherein the unit cells of the first type particularly form high electron mobility transistor (HEMT) cells; and wherein the unit cells of the second type particularly form Schottky Barrier Diode (SBD) cells.

In such a semiconductor device, the inserted SBD unit cells provide current conduction capability in reverse mode without the need of external Schottky diode. By such monolithically integration of SBD unit cells, additional parasitics can be reduced. Integration of SBD cells thus allows replacing the operation of body diodes in semiconductor technologies that do not contain a body diode, like GaN technology, for example. The absence of the body diode function that is used to assist the evacuation of reverse current can be retrieved by such integration of SBD cells.

In an exemplary implementation of the semiconductor device, the semiconductor device comprises a GaN die layer. The GaN die layer allows fast switching and high power due to its wide bandgap which is ˜3.4 eV compared to ˜1.1 eV for Silicon.

In an exemplary implementation of the semiconductor device, each unit cell of the second type comprises a first electrode and a second electrode formed at the top surface of the semiconductor device, in particular the top surface of the die layer; wherein the first electrode is arranged to enclose the second electrode. Accordingly, the unit cells can be space efficiently implemented. Multiple unit cells can be placed side-by-side without waste of die layer.

In an exemplary implementation of the semiconductor device, the first electrode of the unit cell of the second type forms an Anode of the SBD cell and the second electrode of the unit cell of the second type forms a Cathode of the SBD cell; or vice versa. This allows integration of SBD cells with HEMT cells for inhibiting reverse conduction and improving stability at high power and fast switching capabilities.

In an exemplary implementation of the semiconductor device, one or more unit cells of the second type comprise a third electrode formed at the top surface of the semiconductor device, in particular the top surface of the die layer; wherein the third electrode is arranged to enclose the first electrode and the second electrode; or wherein the third electrode is arranged to be enclosed by the first electrode and the second electrode.

In both alternatives, the design allows a space efficient implementation. For example, multiple unit cells can be placed side-by-side without waste of die layer.

In an exemplary implementation of the semiconductor device, the third electrode of the one or more unit cells of the second type forms a Source electrode. The Source electrode is already included in the unit cells of the second type, e.g., the unit cells which form the Schottky Barrier Diode.

In an exemplary implementation of the semiconductor device, the Source electrode is electrically shorted to the Anode of the SBD cell. This improves stability of the semiconductor device since the Source electrode can be directly connected to the Anode of the SBD cell.

In an exemplary implementation of the semiconductor device, the first electrode of the unit cell of the second type forms a closed geometrical contour around the second electrode of the unit cell of the second type. Thus, a bond pad configuration inside the active area of the semiconductor device can be used while in conventional devices packaging can only be implemented with a bond pad configuration outside the active area.

In an exemplary implementation of the semiconductor device, at least one of the first electrode, the second electrode and the third electrode of the unit cell of the second type is stretched in a direction along the top surface of the die layer. This provides design flexibility.

In an exemplary implementation of the semiconductor device, the closed geometrical contour is symmetrical about one or more directions along the top surface of the semiconductor device, in particular the top surface of the die layer; and the closed geometrical contour has at least one sharp corner, at least one rounded corner and/or at least one cut corner or any combination thereof. This provides flexible design and management of eventual electrical field peaks at sharp corners. The contour of the unit cell can be adapted to the available shape of the die layer.

In an exemplary implementation of the semiconductor device, the closed geometrical contour is a hexagon, an octagon, a triangle, a square, a rectangular or a circle. This provides a flexible design. A variety of different designs can be implemented as desired.

In an exemplary implementation of the semiconductor device, the semiconductor device comprises a Gallium Nitride (GaN) layer and an Aluminum Gallium Nitride (AlGaN) layer formed on top of the GaN layer; wherein any of the electrodes of the SBD cell forms a field plate above the AlGaN layer. The field plate allows to shape the electric field at the surface between AlGaN and above layers for protection of Schottky edges and Cathode edges. This improves stability of the semiconductor device.

In an exemplary implementation of the semiconductor device, the first electrode of the unit cell corresponding to the Anode of the SBD cell is laying on top of the AlGaN layer; or the first electrode of the unit cell corresponding to the Anode of the SBD cell is laying on top of a dielectric (or stack of dielectrics) deposited on the AlGaN layer. This design that is further described below with respect to FIGS. 5b (first alternative) and 5a (second alternative) allows flexibility in the layer composition and field management. The dielectric can be formed before the Ohmic metals or after formation of the Ohmic metals.

In an exemplary implementation of the semiconductor device, the first electrode of the unit cell extends into the AlGaN layer without reaching the GaN layer. In such implementation that is also described below with respect to FIG. 5c, the Cathode and/or Anode terminals can be formed by etching away most of the barrier thickness, e.g. the AlGaN layer.

In an exemplary implementation of the semiconductor device, the first electrode of the unit cell extends into the AlGaN layer up to the GaN layer without extending into the GaN layer. In such implementation that is also described below with respect to FIG. 5d, the Cathode and/or Anode terminals can be formed by etching away all of the barrier thickness, e.g., the AlGaN layer.

In an exemplary implementation of the semiconductor device, the first electrode of the unit cell extends into the AlGaN layer and further extends into the GaN layer. In such implementation also described below with respect to FIGS. 5a and 5b, the Cathode and/or Anode terminals can be formed by etching away all of the barrier thickness, e.g. the AlGaN layer, and additionally part of the GaN layer.

In an exemplary implementation of the semiconductor device, field plates of the first electrode of the unit cell corresponding to the Anode of the SBD cell, the second electrode of the unit cell corresponding to the Cathode of the SBD cell and the gate electrode of the HEMT cell are arranged at different heights above the top surface of the semiconductor device, in particular the top surface of the die layer. This configuration of field plates allows to design the electric field at or above the top surface of the die layer.

In an exemplary implementation of the semiconductor device, one or more SBD cells are inserted into a block of HEMT cells; wherein a number of SBD cells and a number of HEMT cells of the semiconductor device is based on a ratio between forward conduction and reverse conduction of the semiconductor device. This allows to control forward conduction and reverse conduction of the semiconductor device.

In an exemplary implementation of the semiconductor device, the one or more unit cells of the first type and the second type are arranged in a staggered pattern across the top surface of the semiconductor device, in particular the top surface of the die layer, without forming areas of the die layer in between the unit cells or at least subareas thereof which are not occupied by unit cells; or the one or more unit cells of the first type and the second type are aligned with respect to each other such that areas of the die layer in between the unit cells or at least subareas thereof are formed which are not occupied by unit cells.

In an exemplary implementation, the area of the die layer is efficiently utilized without leaving unused spaces in between the unit cells. In an exemplary implementation, the unit cells can be flexibly designed, for example, from a metallization and spacing point of view.

Even in the staggered pattern layout there can be areas of the die not occupied by the unit cell, for example at the edges of the block.

Areas of the die layer in between the unit cells can cover the whole area between the unit cells of a unit block, or only a portion of this whole area, in this case, these areas are denoted as subareas. These subareas can be connected with each other and/or can be isolated from each other.

In an exemplary implementation of the semiconductor device, the semiconductor device comprises: one or more first metal tracks for routing Drain currents of the HEMT cells and Cathode currents of the SBD cells.

These metal tracks can run over the top surface of the die layer to collect the Drain currents of the HEMT cells and the Cathode currents of the SBD cells.

In an exemplary implementation of the semiconductor device, the semiconductor device comprises: one or more second metal tracks for routing Source currents of the HEMT cells and Anode currents of the SBD cells; wherein a thickness of the one or more second metal tracks is greater in an area above the SBD cells than in an area above the HEMT cells for shortcutting a Source electrode of a respective SBD cell with an Anode of the SBD cell.

These second metal tracks run in a second layer over the top surface of the semiconductor device, in particular the top surface of the die layer to independently collect the Source currents of the HEMT cells and the Anode currents of the SBD cells. By these second metal tracks, the Source electrode of an SBD cell can be electrically connected to the Anode of the SBD cell.

According to a second aspect, the disclosure relates to a method for manufacturing a semiconductor device, the method comprising: forming a plurality of unit cells arranged side-by-side across a top surface of the semiconductor device, in particular across a top surface of a die layer, wherein the plurality of unit cells are of a first type or a second type; forming for each unit cell of the first type a first electrode, a second electrode and a third electrode at the top surface of the semiconductor device such that the second electrode is arranged to enclose the first electrode; and each of the first and second electrodes is arranged to enclose the third electrode; wherein the unit cells of the first type particularly form high electron mobility transistor, HEMT, cells; and wherein the unit cells of the second type particularly form Schottky Barrier Diode, SBD, cells.

In such a method, the inserted SBD unit cells provide current conduction capability in reverse mode without the need of external Schottky diode. By such monolithically integration of SBD unit cells, additional parasitics can be reduced. Integration of SBD cells thus allows replacing the operation of body diodes in semiconductor technologies that do not contain a body diode, like GaN technology, for example. The absence of the body diode function that is used to assist the evacuation of reverse current can be retrieved by such integration of SBD cells.

In an exemplary implementation of the method, the method comprises: forming for each unit cell of the second type a first electrode and a second electrode at the top surface of the semiconductor device such that the first electrode is arranged to enclose the second electrode; and forming for each unit cell of the second type a third electrode at the top surface of the semiconductor device.

By such a manufacturing method, the unit cells can be space efficiently implemented. Multiple unit cells can be placed side-by-side without waste of die layer.

In an exemplary implementation of the method, a gate metal of a unit cell of the second type is formed before the first electrode of a unit cell of the second type representing an Anode electrode is formed; or the first electrode of a unit cell of the second type representing an Anode electrode is formed before a gate metal of the unit cell of the second type is formed.

An exemplary embodiment allows implementing of the Gate first concept for manufacturing the semiconductor device, e.g., the gate module is created first (until the gate metal), then the Anode and the Ohmic contact or metals are formed, as described below with respect to FIG. 6a. An exemplary embodiment allows implementing of the Gate last concept for manufacturing the semiconductor device, e.g., the Anode and the Ohmic contacts are created first and the gate module is created afterwards, as described below with respect to FIG. 6b.

In an exemplary implementation of the method, the method comprises: forming one or more field plates from a gate metal by splitting the gate metal into one or more parts; and/or forming one or more field plates from an Ohmic metal of the second electrode of a unit cell of the second type representing a source electrode by splitting the Ohmic metal into one or more parts.

The first part is described below with respect to FIG. 6c and the second part is described below with respect to FIG. 6d. In the latter two implementations, the one or more parts of the split metal can be left electrically floating or can be set to another potential (ex. Connected to the source electrode to set its potential to the ground).

Forming field plates allows to design the electric field at or above the top surface of the die layer.

In an exemplary implementation of the method, the method comprises: forming a dielectric layer above the top surface of the semiconductor device and one or more additional metal layers on top of the dielectric layer, the one or more additional metal layers acting as one or more additional field plates. The additional metal layers can also be split. They can also be connected to other electrodes through vias in the cross section of the device or outside the cross section.

### BRIEF DESCRIPTION OF THE DRAWINGS

Further embodiments of the disclosure will be described with respect to the following figures, in which:

FIG. 1a shows a schematic diagram of a semiconductor device 100 according to the present disclosure;

FIG. 1b shows a schematic top view of a unit cell 120a of a first type and a unit cell 120b of a second type according to a first embodiment;

FIG. 2 shows a schematic top view of a unit cell 120a of a first type and a unit cell 120b of a second type according to a second embodiment;

FIG. 3 shows a schematic top view of a unit cell 120a of a first type and a unit cell 120b of a second type according to a third embodiment;

FIG. 4 shows a schematic top view of a unit cell 120a of a first type and a unit cell 120b of a second type according to a fourth embodiment;

FIG. 5a shows a schematic cross section of a unit cell 120b of a second type according to a fifth embodiment;

FIG. 5b shows a schematic cross section of a unit cell 120b of a second type according to a sixth embodiment;

FIG. 5c shows a schematic cross section of a unit cell 120b of a second type according to a seventh embodiment;

FIG. 5d shows a schematic cross section of a unit cell 120b of a second type according to an eighth embodiment;

FIG. 6a shows a schematic cross section of a unit cell 120b of a second type according to a ninth embodiment;

FIG. 6b shows a schematic cross section of a unit cell 120b of a second type according to a tenth embodiment;

FIG. 6c shows a schematic cross section of a unit cell 120b of a second type according to an eleventh embodiment;

FIG. 6d shows a schematic cross section of a unit cell 120b of a second type according to a twelfth embodiment;

FIG. 7a shows a schematic top view of a semiconductor device 100 in a staggered configuration (left picture) and in an aligned configuration (right picture) according to an embodiment;

FIG. 7b shows a schematic top view of a semiconductor device 100 in a staggered configuration (left picture) and in an aligned configuration (right picture) with vias 708 according to an embodiment;

FIG. 7c shows a schematic top view of a semiconductor device 100 in a staggered configuration (left picture) and in an aligned configuration (right picture) with metal tracks 711 according to an embodiment;

FIG. 7d shows a schematic top view of a semiconductor device 100 in a staggered configuration (left picture) and in an aligned configuration (right picture) with second metal tracks 710 according to an embodiment; and

FIG. 8 shows a schematic diagram illustrating a method 800 for manufacturing a semiconductor device according to the present disclosure.

### DETAILED DESCRIPTION

In the following detailed description, reference is made to the accompanying drawings, which form a part thereof, and in which is shown by way of illustration specific aspects in which the disclosure may be practiced. It is understood that other aspects may be utilized and structural or logical changes may be made without departing from the scope of the disclosure. The following detailed description, therefore, is not to be taken in a limiting sense, and the scope of the disclosure is defined by the appended claims.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

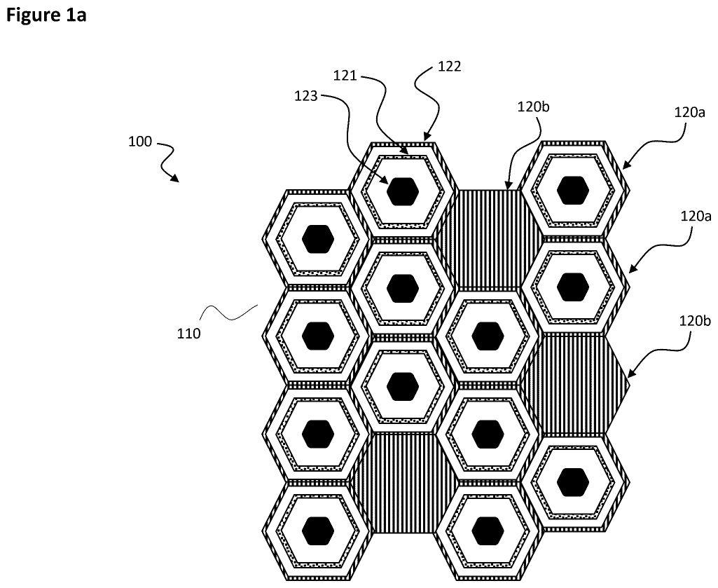

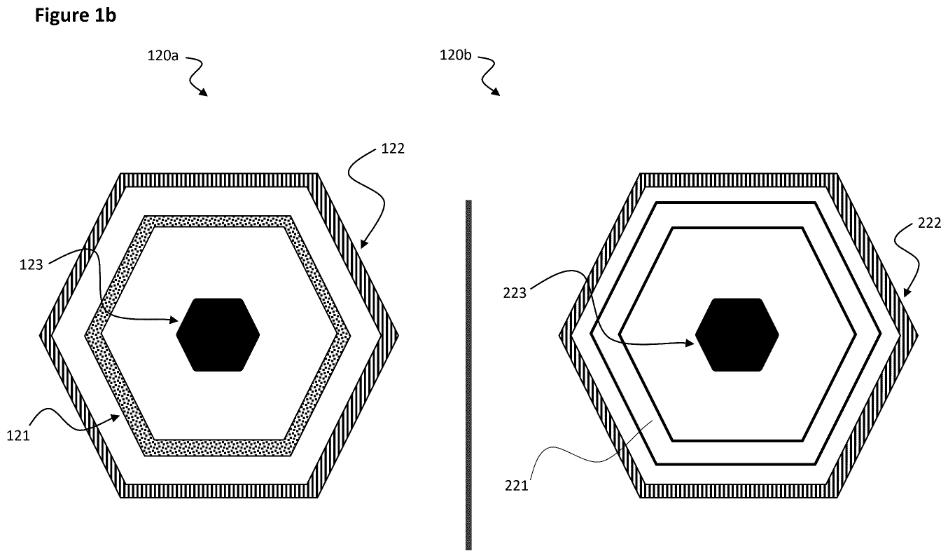

FIG. 1a shows a schematic diagram of a semiconductor device 100 according to the present disclosure.

FIG. 1a is an exemplary implementation of such a semiconductor device. In this example, an exemplary unit block is illustrated which includes an exemplary number of 16 unit cells. It should be understood that any other number of unit cells can be used as well in embodiments of the present disclosure. In this example, an exemplary number of three unit cells out of the 16 unit cells are unit cells of a second type, which are distributed SBD devices. In this example, an exemplary number of 13 unit cells out of the 16 unit cells are unit cells of a first type, which are HEMT devices. It should be understood that any other distribution between unit cells of the first type and unit cells of the second type can be applied as well in embodiments of the present disclosure. The unit cell configuration, e.g., the closed unit cell, has a hexagonal shape in this example. It should be understood that other closed geometries can be applied as well in embodiments of the present disclosure.

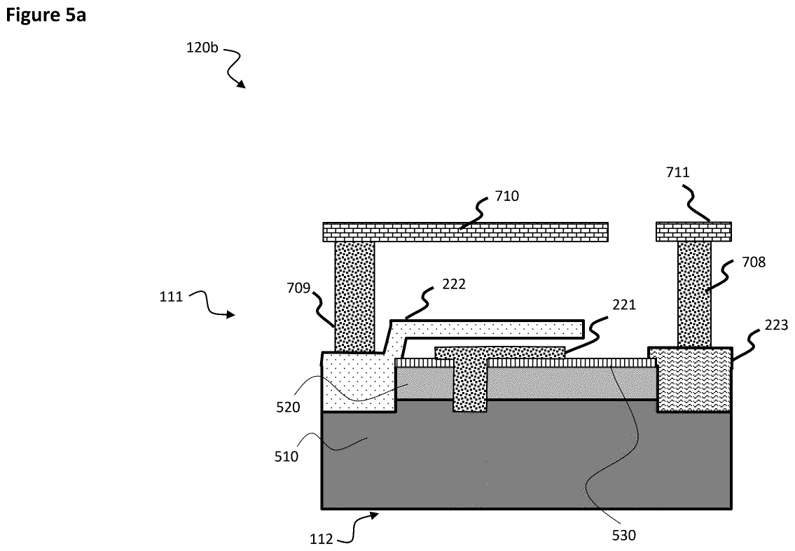

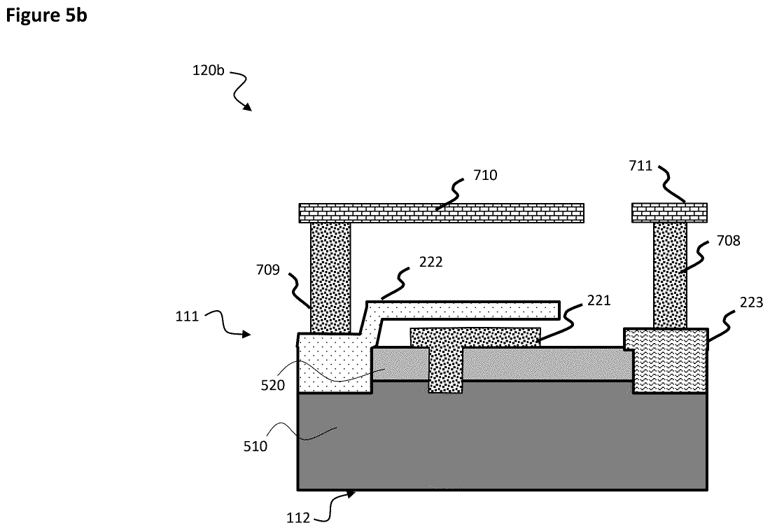

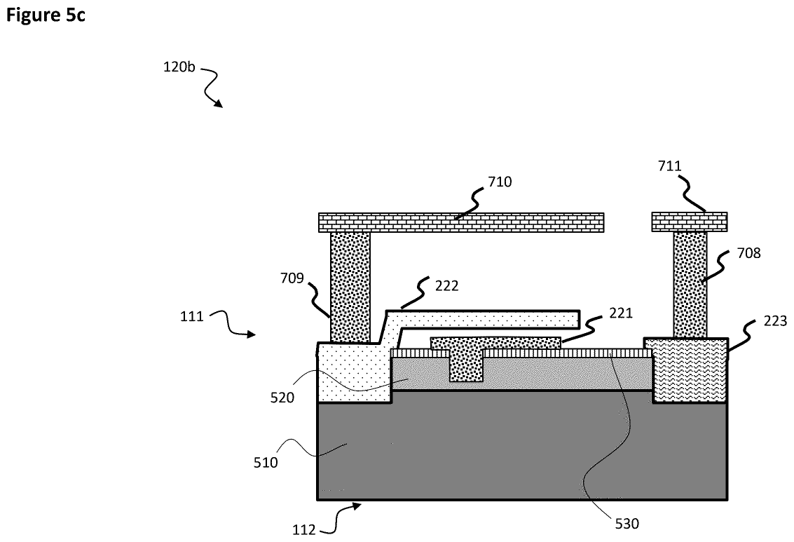

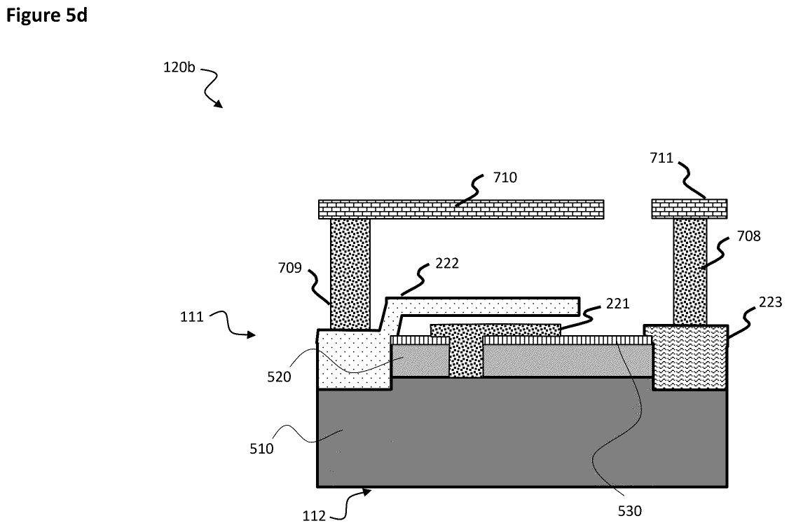

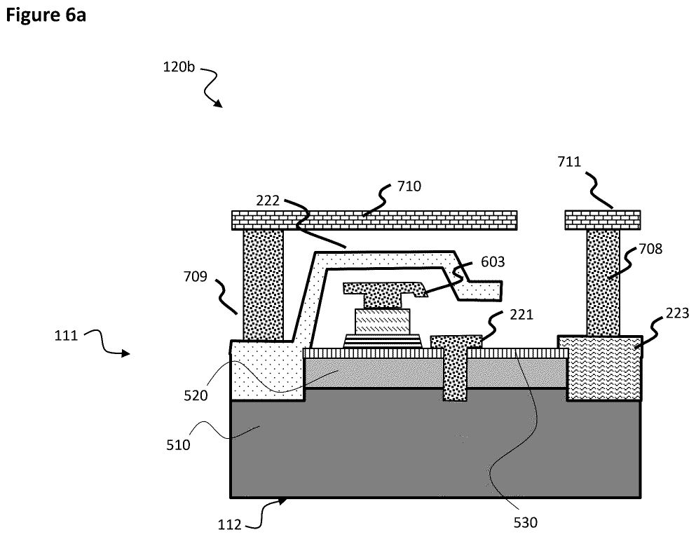

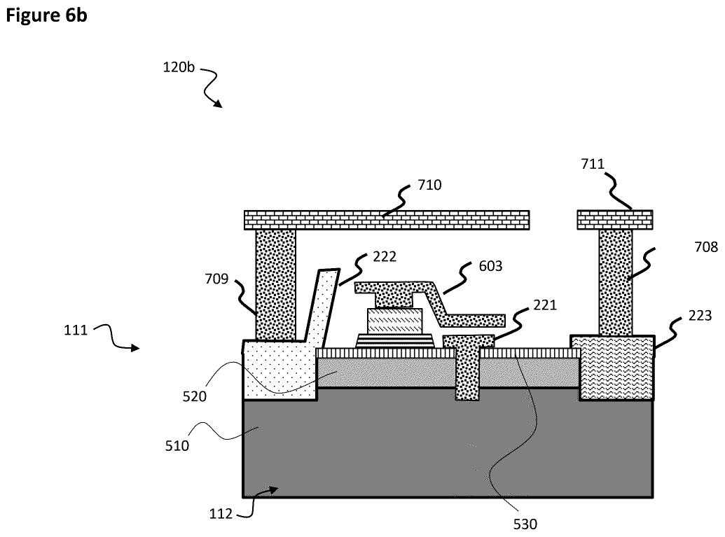

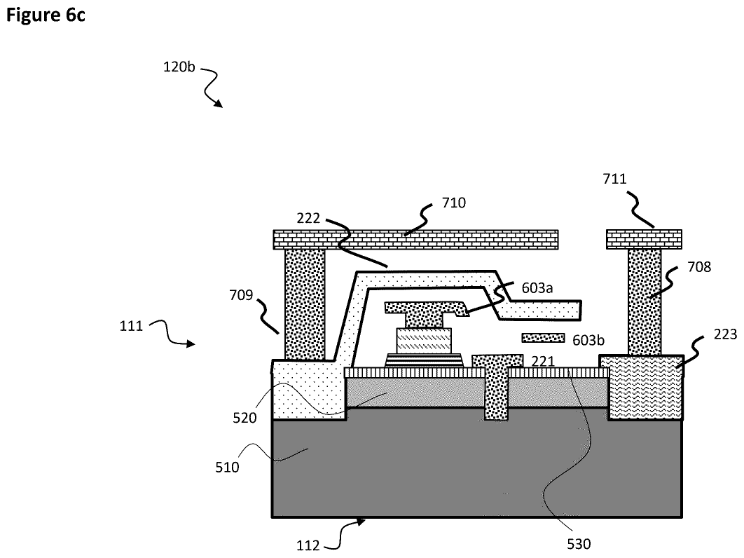

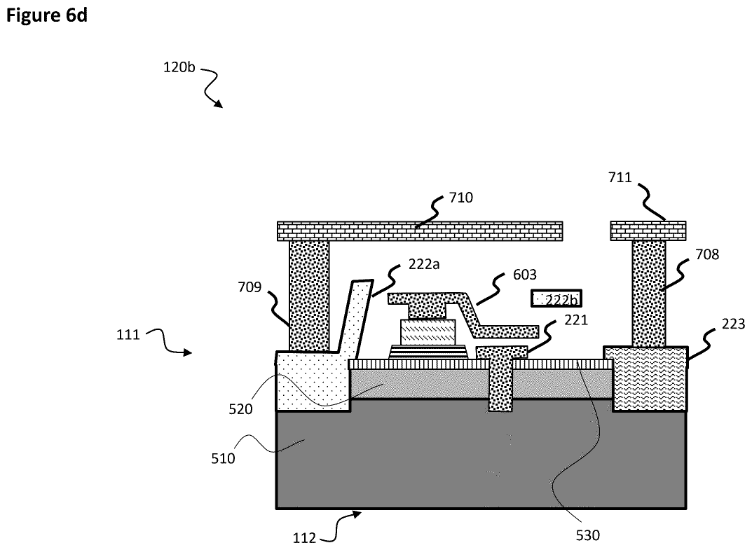

The semiconductor device 100 shown in FIG. 1a comprises: a die layer 110 comprising a top surface and a bottom surface opposing the top surface. FIG. 1a shows a top view on the top surface of the semiconductor device 100. Exemplary cross sections are shown in FIGS. 5a to 6d. The top surface of the die layer 110 is referred to as the top surface of the semiconductor device 100.

The semiconductor device 100 comprises a plurality of unit cells 120a, 120b which are arranged side-by-side across the top surface of the semiconductor device 100. As described above, the plurality of unit cells 120a, 120b are of a first type 120a or a second type 120b. Each unit cell 120a of the first type comprises a first electrode 121, a second electrode 122 and a third electrode 123 formed at the top surface of the semiconductor device 100, in particular a top surface of the die layer 110.

The second electrode 122 is arranged to enclose the first electrode 121.

Each of the first and second electrodes 121, 122 is arranged to enclose the third electrode 123.

The unit cells of the first type 120a may form HEMT cells, for example. The unit cells of the second type 120b may form SBD cells, for example.

In a general implementation, the unit cells form unit cells of a first type 120a and unit cells of a second type 120b. In the implementation described hereinafter, these unit cells of the first type 120a form HEMT cells and these unit cells of the second type 120b form SBD cells.

Thus, the inserted SBD unit cells 120b provide current conduction capability in reverse mode without the need of external Schottky diode. By such monolithically integration of SBD unit cells 120b, additional parasitics can be reduced. Integration of SBD cells 120b replaces the operation of body diodes in semiconductor technologies that do not contain a body diode, like GaN technology, for example. The absence of the body diode function that is used to assist the evacuation of reverse current can be retrieved by such integration of SBD cells 120b.

The die layer 110 may comprise a GaN die layer, for example.

FIG. 1b shows a schematic top view of a unit cell 120a of a first type (left picture) and a unit cell 120b of a second type (right picture) according to a first embodiment.

The unit cell 120a of the first type and the unit cell 120b of the second type are examples of the respective unit cells 120a, 120b described above with respect to FIG. 1a.

Each unit cell of the second type 120b comprises a first electrode 221 and a second electrode 223 formed at the top surface 111 of the semiconductor device 100, in particular a top surface of the die layer 110. The first electrode 221 is arranged to enclose the second electrode 223.

The first electrode 221 of the unit cell of the second type 120b forms an Anode of the SBD cell 120b and the second electrode 223 of the unit cell of the second type 120b forms a Cathode of the SBD cell 120b as shown in FIG. 1b; or vice versa.

One or more unit cells of the second type 120b comprise a third electrode 222 formed at the top surface 111 of the semiconductor device 100, in particular a top surface of the die layer 110. The third electrode 222 is arranged to enclose the first electrode 221 and the second electrode 223 as shown in FIG. 1b. Alternatively, the third electrode 222 may be arranged to be enclosed by the first electrode 221 and the second electrode 223.

The third electrode 222 of the one or more unit cells of the second type 120b forms a Source electrode 222 as shown in FIG. 1b.

The Source electrode 222 may be electrically shorted to the Anode 221 of the SBD cell 120b.

As shown in FIG. 1b (right side), the first electrode 221 of the unit cell of the second type 120b forms a closed geometrical contour around the second electrode 223 of the unit cell of the second type 120b.

This closed geometrical contour is symmetrical about one or more directions along the top surface of the die layer 110. Such closed geometrical contour may have, for example, at least one sharp corner, at least one rounded corner, and/or at least one cut corner or any combination thereof.

The closed geometrical contour can be a hexagon as shown in FIG. 1b or alternatively an octagon, a triangle, a square, a rectangular, or a circle.

In particular, in the left picture of FIG. 1b, an example of a hexagonal unit cell is depicted, hereinafter referred to as unit cell of a first type 120a or HEMT cell 120a. In this case, Drain 123 is inside, Source 122 outside, and the Gate 121 between Source 122 and Drain 123, with appropriate spacing to Drain 123 to sustain the targeted high voltage.

The right picture of FIG. 1b represents Embodiment 1. It represents a unit cell of a second type 120b or an SBD cell 120b that is derived from the GaN HEMT cell 120a where the inner terminal is forming the Cathode 223, and the Schottky contact 221 (Anode) is surrounding the Cathode 223, e.g., the Schottky contact 221 is between Source 222 and Cathode 223 and the Cathode 223 is inside.

The Source terminal 222 is kept and can be shorted electrically to the Anode terminal 221.

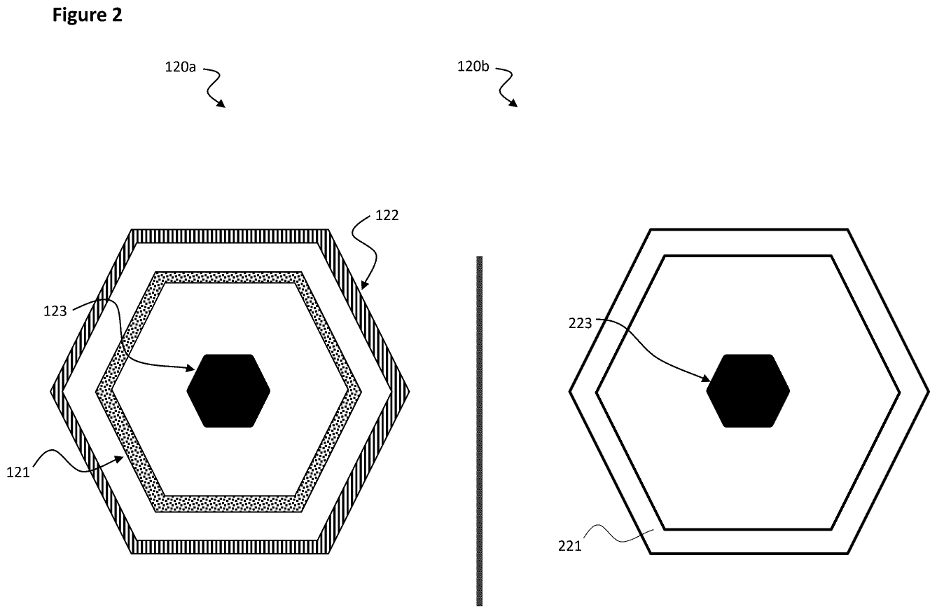

FIG. 2 shows a schematic top view of a unit cell 120a of a first type (left picture) and a unit cell 120b of a second type (right picture) according to a second embodiment.

The unit cell 120a of the first type and the unit cell 120b of the second type are examples of the respective unit cells 120a, 120b described above with respect to FIG. 1a.

In this second embodiment, Schottky contact 221 is used instead of Source and the Cathode 223 is inside.

FIG. 2 (right picture) shows Embodiment 2 where the Source terminal is not implemented allowing a larger distance between the Cathode 223 and the Anode 221 (higher voltage capability). Ultimately, the Anode is implemented instead of the Source (which offers the maximum distance allowed in the unit cell between Cathode and Anode).

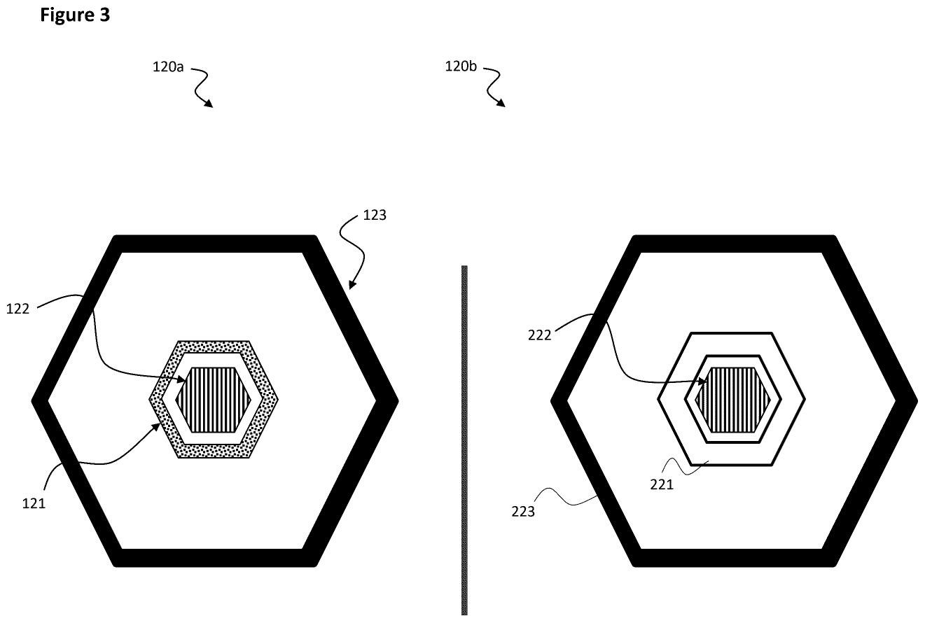

FIG. 3 shows a schematic top view of a unit cell 120a of a first type (left picture) and a unit cell 120b of a second type (right picture) according to a third embodiment.

The unit cell 120a of the first type and the unit cell 120b of the second type are examples of the respective unit cells 120a, 120b described above with respect to FIG. 1a.

FIG. 3 (right picture) shows another configuration which is based on the HEMT configuration or HEMT unit cell 120a depicted in the left picture of FIG. 3. In this case, the Schottky contact (Anode) 221 is implemented around the Source 222 (which is in the inner part of the hexagonal unit cell 120b). The Cathode 223 is inserted at the outer side.

The hexagonal shape of the unit cell 120b is only an example. As described above, other closed geometrical shapes can be applied as well.

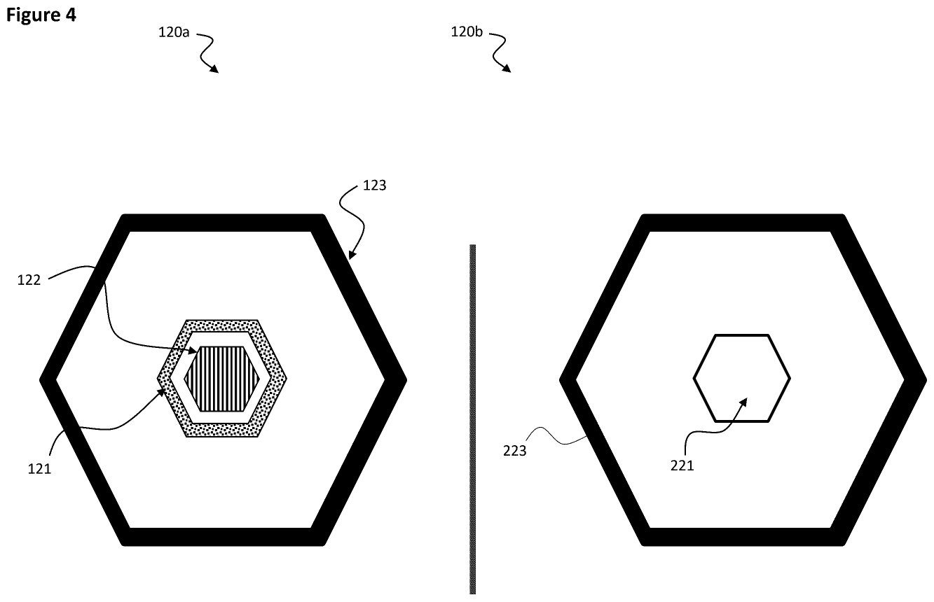

FIG. 4 shows a schematic top view of a unit cell 120a of a first type (left picture) and a unit cell 120b of a second type (right picture) according to a fourth embodiment.

The unit cell 120a of the first type and the unit cell 120b of the second type are examples of the respective unit cells 120a, 120b described above with respect to FIG. 1a.

This fourth embodiment is built up without the inner Source terminal, the whole inner space is occupied by the Schottky contact (Anode) 221, thereby increasing the current capability of the SBD 120b.

Alternatively, the distance between Anode 221 and Cathode 223 can be increased providing extra blocking voltage capability.

In the previous embodiments, the hexagonal cell configurations were discussed. In the next Embodiment 5 to 12, the implementation from a cross section point of view is discussed.

In the cross sections shown in Embodiments 5 to 12, all white spaces above the AlGaN layer 520 may be covered by dielectrics unless otherwise noted. In some parts above the AlGaN layer 520 and below the Anode 221 there may be no dielectrics as described below.

FIG. 5a shows a schematic cross section of a unit cell 120b of a second type according to a fifth embodiment.

In particular, FIG. 5a is a cross section of a GaN SBD implementation applicable for the few unit cells 120b that are foreseen for the SBD implementation. This is applicable to all previous embodiments.

This fifth embodiment shows the use of any present metal layer as a field plate to shape the electric field at the surface between AlGaN and above layers (protection of Schottky edges and Cathode edges).

The dielectric(s) can be present on top of the AlGaN layer (below the Anode (221)) as shown in FIG. 5a or the dielectric(s) can be absent on top of the AlGaN layer (below the Anode (221)).

The unit cell 120b of the second type shown in FIG. 5a is an example of the cell 120b of the second type described above with respect to FIG. 1a.

As can be seen from FIG. 5a, the die layer 110 shown in FIG. 1a comprises a Gallium Nitride (GaN) layer 510 and an Aluminum Gallium Nitride (AlGaN) layer 520 formed on top of the GaN layer 510. Any of the electrodes 221, 223, 222 of the SBD cell 120b forms a field plate above the AlGaN layer 520. Extra field plates can be formed by splitting the electrodes 221, 223, 222, or by additional metals. Metals 710 and 711 can be used as field plates.

The first electrode 221 of the unit cell 120b corresponding to the Anode 221 of the SBD cell 120b is laying on top of a dielectric 530 deposited on the AlGaN layer 520 as can be seen from FIG. 5a.

Alternatively, the first electrode 221 of the unit cell 120b corresponding to the Anode 221 of the SBD cell 120b can be laying on top of the AlGaN layer 520 as shown in FIG. 5b, for example, where no dielectric 530 is used.

The first electrode 221 of the unit cell 120b extends into the AlGaN layer 520 and further extends into the GaN layer 510.

As can be seen from FIG. 5a, a via 709 is placed on top of the Ohmic metal forming the third electrode 222 which electrically connects the third electrode 222 with a source metal 710 above the top surface 111 of the die layer 110.

Another via 708 is placed on top of the Ohmic metal forming the second electrode 223 (Cathode) which electrically connects the second electrode 223 with a Cathode metal 711 above the top surface 111 of the die layer 110.

FIG. 5b shows a schematic cross section of a unit cell 120b of a second type according to a sixth embodiment.

In this sixth embodiment, the top part of the Cathode 711 and/or the Anode metals can be laying on top of the AlGaN barrier 520 as shown in FIG. 5b.

The dielectric(s) can be present on top of the AlGaN layer 520 (below the Anode (221)) or the dielectric(s) can be absent on top of the AlGaN layer 520 (below the Anode (221)) as shown in FIG. 5b.

As described above with respect to FIG. 5a, a via 709 is placed on top of the Ohmic metal forming the third electrode 222 which electrically connects the third electrode 222 with a source metal 710 above the top surface 111 of the die layer 110. Another via 708 is placed on top of the Ohmic metal forming the second electrode 223 (Cathode) which electrically connects the second electrode 223 with a Cathode metal 711 above the top surface 111 of the die layer 110.

FIG. 5c shows a schematic cross section of a unit cell 120b of a second type according to a seventh embodiment.

The configuration is similar to FIGS. 5a and 5b, e.g., a via 709 is placed on top of the Ohmic metal forming the third electrode 222 which electrically connects the third electrode 222 with a source metal 710 above the top surface 111 of the die layer 110. Another via 708 is placed on top of the Ohmic metal forming the second electrode 223 (Cathode) which electrically connects the second electrode 223 with a Cathode metal 711 above the top surface 111 of the die layer 110.

In this seventh embodiment, the first electrode 221 of the unit cell extends into the AlGaN layer 520 without reaching the GaN layer 510.

In this seventh embodiment, the top part of the Cathode and/or the Anode metals can be laying on top of a dielectric (or dielectrics) deposited on top of the AlGaN barrier 520 as shown in FIG. 5c. In this case this dielectric(s) is formed before the Ohmic metals 222, 223; however, the opposite case can also be implemented.

In this seventh embodiment, the Cathode and/or the Anode terminals can be formed by etching away most of the barrier thickness.

The dielectric(s) can be present on top of the AlGaN layer 520 as shown in FIG. 5c or the dielectric(s) can be absent on top of the AlGaN layer.

FIG. 5d shows a schematic cross section of a unit cell 120b of a second type according to an eighth embodiment.

The configuration is similar to FIGS. 5a to 5c, e.g., a via 709 is placed on top of the Ohmic metal forming the third electrode 222 which electrically connects the third electrode 222 with a source metal 710 above the top surface 111 of the die layer 110. Another via 708 is placed on top of the Ohmic metal forming the second electrode 223 (Cathode) which electrically connects the second electrode 223 with a Cathode metal 711 above the top surface 111 of the die layer 110.

In this configuration, the first electrode 221 of the unit cell extends into the AlGaN layer 520 up to the GaN layer 510 without extending into the GaN layer 510.

In this eighth embodiment, the Cathode 223 and/or the Anode 221 terminals can be formed by etching away all of the barrier 520 thickness.

The dielectric(s) can be present on top of the AlGaN layer 520 as shown in FIG. 5d or the dielectric(s) can be absent on top of the AlGaN layer.

FIG. 6a shows a schematic cross section of a unit cell 120b of a second type according to a ninth embodiment.

The configuration is similar to FIGS. 5a to 5c, e.g., a via 709 is placed on top of the Ohmic metal forming the third electrode 222 which electrically connects the third electrode 222 with a source metal 710 above the top surface 111 of the die layer 110. Another via 708 is placed on top of the Ohmic metal forming the second electrode 223 (Cathode) which electrically connects the second electrode 223 with a Cathode metal 711 above the top surface 111 of the die layer 110.

As can be seen from FIG. 6a, the field plates of the first electrode 221 of the unit cell 120b corresponding to the Anode 221 of the SBD cell 120b and field plates of the second electrode 223 of the unit cell corresponding to the Cathode 223 of the SBD cell 120b and field plates of the gate electrode 603 of the SBD cell 120b may be arranged at different heights above the top surface of the die layer 110. Note that in the SBD cell 120b, the gate module is still present to benefit from the 603 metal as field plate. However, the gate module is not active in the SBD cell 120b as in a HEMT 120a, but rather connected to source electrode and acts as a field plate.

In this ninth embodiment, the Cathode and/or the Anode terminals can be formed by etching away all of the barrier 520 thickness and extending through the layer 510 below the AlGaN barrier 520. In this configuration, the Anode 221 is extending through the GaN layer 510. Note that other configurations can be provided as well, where the Anode 221 is not reaching the GaN layer 510 or where the Anode 221 is stopping at the GaN layer 510.

The Anode 221 can be integrated next to the Gate terminal 603, e.g., between Gate 603 and Cathode 223. In this case, two configurations can be implemented depending on the technology: 1) Gate first concept: In this configuration, the gate module is created first (until the gate metal 603), then the Anode 221 and the ohmic contact/metals are formed as shown in FIGS. 6a; and 2) Gate last concept as described below with respect to FIG. 6b.

The dielectric(s) can be present on top of the AlGaN layer 520 as shown in FIG. 6a or the dielectric(s) can be absent on top of the AlGaN layer 520.

FIG. 6b shows a schematic cross section of a unit cell 120b of a second type according to a tenth embodiment. The configuration is similar to that described above with respect to FIG. 6a.

As described above, the Anode can be integrated next to the Gate terminal (between Gate and Cathode). In this case, the two configurations can be implemented depending on the technology: 1) Gate first concept as described above with respect to FIGS. 6a; and 2) Gate last concept as shown here in FIG. 6b: The Anode 223 and the Ohmic contacts/metals are created first. The Gate module 603 is created afterwards.

The dielectric(s) can be present on top of the AlGaN layer 520 as shown in FIG. 6b or the dielectric(s) can be absent on top of the AlGaN layer 520.

FIG. 6c shows a schematic cross section of a unit cell 120b of a second type according to an eleventh embodiment. The configuration is similar to that described above with respect to FIGS. 6a and 6b.

The dielectric(s) can be present on top of the AlGaN layer 520 as shown in FIG. 6c or the dielectric(s) can be absent on top of the AlGaN layer 520.

Extra field plates 603a, 603b can be designed by splitting the Gate metal as shown in FIG. 6c.

FIG. 6d shows a schematic cross section of a unit cell 120b of a second type according to a twelfth embodiment.

The dielectric(s) can be present on top of the AlGaN layer 520 as shown in FIG. 6d or the dielectric(s) can be absent on top of the AlGaN layer 520.

Extra field plates 222a, 222b can be designed by splitting the Source Ohmic metal as shown in FIG. 6d.

Any of the previous closed cells described previously can be used as a SBD unit cell 120b inserted in a block of cells containing HEMT closed unit cells 120a. The number of SBD cells 120b and the number of HEMT cells 120a can be decided by the ratio between forward conduction and reverse conduction.

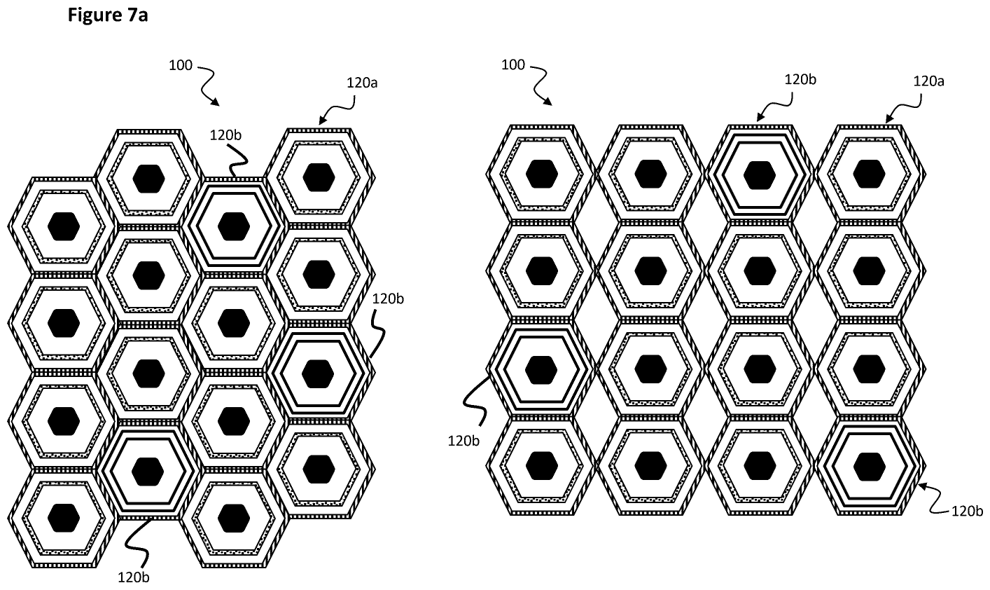

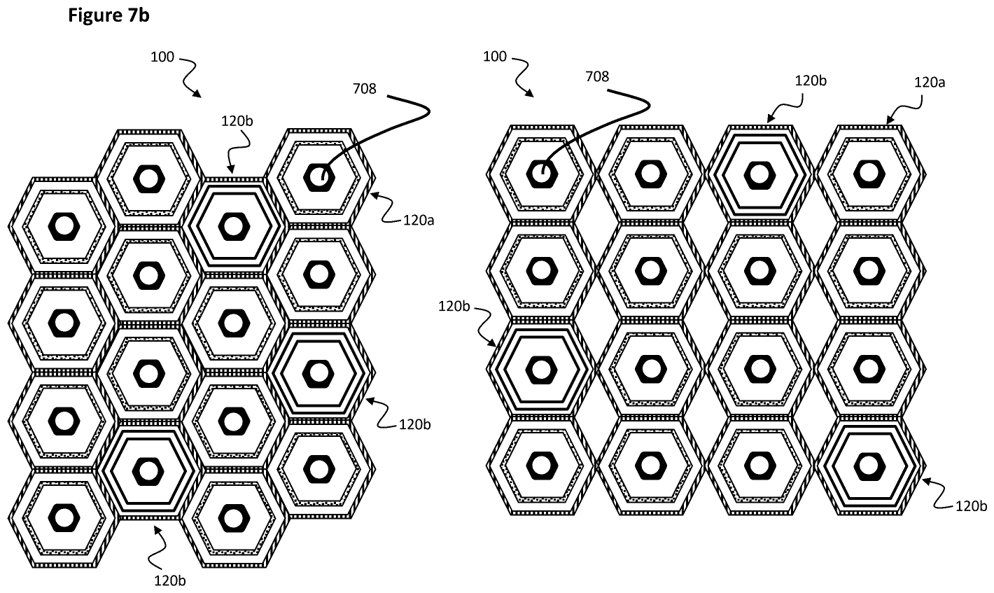

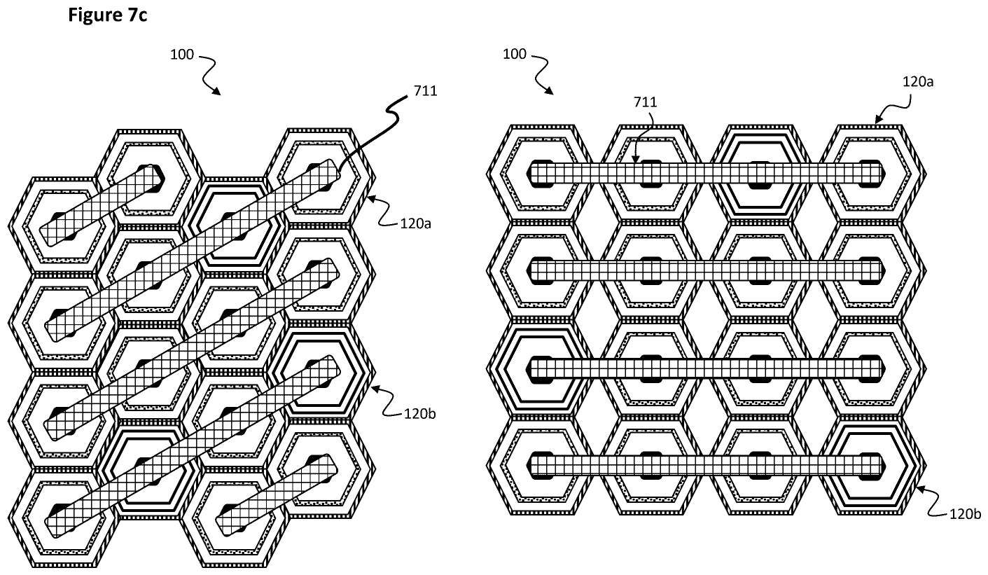

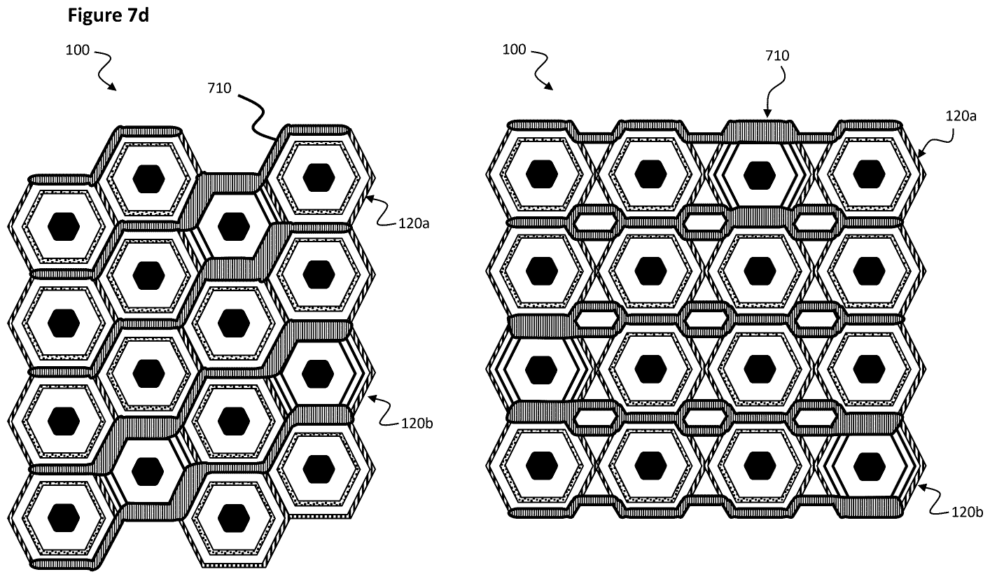

FIG. 7a shows two examples of cell blocks including an exemplary number of three SBD cells 120b. The left picture in FIG. 7a depicts a staggered configuration, while the right picture in FIG. 7a depicts an aligned configuration.

In this embodiment, one or more SBD cells 120b are inserted into a block of HEMT cells 120a. A number of SBD cells 120b and a number of HEMT cells 120a of the semiconductor device 100 may be based on a ratio between forward conduction and reverse conduction of the semiconductor device 100.

In the configuration shown in the left picture of FIG. 7a, the one or more unit cells of the first type 120a and the second type 120b are arranged in a staggered pattern across the top surface of the die layer 110 without forming areas of the die layer 110 in between the unit cells 120a, 120b or at least subareas thereof which are not occupied by unit cells 120a, 120b.

In the configuration shown in the right picture of FIG. 7a, the one or more unit cells of the first type 120a and the second type 120b are aligned with respect to each other such that areas of the die layer 110 in between the unit cells 120a, 120b or at least subareas thereof are formed which are not occupied by unit cells 120a, 120b.

The SBD unit cell 120b inserted here as example is the one from the first embodiment described above with respect to FIG. 1b.

Note that any embodiment described above can be inserted in a block of cells.

A mix of any of the previous embodiments can be inserted.

FIG. 7b shows a schematic top view of a semiconductor device 100 in a staggered configuration (left picture) and in an aligned configuration (right picture) with vias 708 according to an embodiment.

In particular, FIG. 7b shows an example of Vias 708 opening.

FIG. 7c shows a schematic top view of a semiconductor device 100 in a staggered configuration (left picture) and in an aligned configuration (right picture) with metal tracks 711 according to an embodiment.

The semiconductor devices 100 shown in FIG. 7c comprise one or more first metal tracks 711 arranged above the die layer 110 for routing Drain currents of the HEMT cells 120a and Cathode currents of the SBD cells 120b.

FIG. 7d shows a schematic top view of a semiconductor device 100 in a staggered configuration (left picture) and in an aligned configuration (right picture) with second metal tracks 710 according to an embodiment.

The semiconductor devices 100 shown in FIG. 7d comprise one or more second metal tracks 710 arranged above the die layer 110 for routing Source currents of the HEMT cells 120a and Anode currents of the SBD cells 120b.

As can be seen from FIG. 7d, a thickness of the one or more second metal tracks 710 can be greater in an area above the SBD cells 120b than in an area above the HEMT cells 120a for shortcutting a Source electrode of a respective SBD cell 120b with an Anode of the SBD cell 120b.

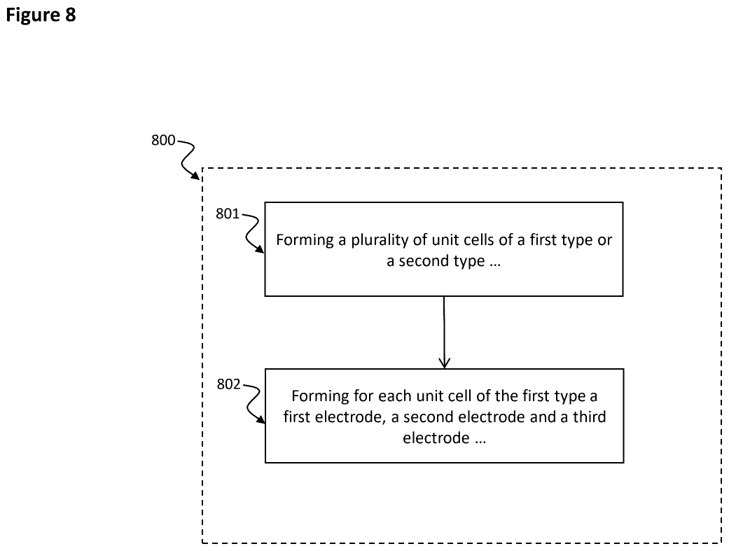

FIG. 8 shows a schematic diagram illustrating a method 800 for manufacturing a semiconductor device according to the disclosure.

The semiconductor device may correspond to one of the semiconductor devices 100 described above with respect to FIGS. 1a to 7d.

The method 800 comprises: forming 801 a plurality of unit cells 120a, 120b arranged side-by-side across a top surface of the semiconductor device 100, wherein the plurality of unit cells 120a, 120b are of a first type 120a or a second type 120b, e.g., as described above with respect to FIG. 1a.

The method 800 comprises: forming 802 for each unit cell 120a of the first type a first electrode 121, a second electrode 122 and a third electrode 123 at the top surface 111 of the semiconductor device 100 such that the second electrode 122 is arranged to enclose the first electrode 121; and each of the first and second electrodes 121, 122 is arranged to enclose the third electrode 123, e.g., as described above with respect to FIG. 1a; wherein the unit cells of the first type 120a may form high electron mobility transistor, HEMT, cells; and wherein the unit cells of the second type 120b may form Schottky Barrier Diode, SBD, cells.

The method 800 may further comprise: forming for each unit cell of the second type 120b a first electrode 221 and a second electrode 223 at the top surface 111 of the semiconductor device 100 such that the first electrode 221 is arranged to enclose the second electrode 223; and forming for each unit cell of the second type 120b a third electrode 222 at the top surface 111 of the semiconductor device 100, e.g., as described above with respect to FIGS. 1a to 7d.

The gate electrode 603 of a unit cell 120b of the second type may be formed before the first electrode 221 of a unit cell 120b of the second type representing an Anode electrode is formed. Note that in the SBD cell 120b, the gate module is still present to benefit from the 603 metal as field plate. However, the gate module is not active in the SBD cell 120b as in a HEMT 120a, but rather connected to source electrode and acts as a field plate.

Alternatively, the first electrode 221 of a unit cell 120b of the second type representing an Anode electrode may be formed before the gate electrode 603 of the unit cell 120b of the second type is formed. As mentioned above, in the SBD cell 120b, the gate module is still present to benefit from the 603 metal as field plate. However, the gate module is not active in the SBD cell 120b as in a HEMT 120a, but rather connected to source electrode and acts as a field plate.

The method 800 may further comprise: forming one or more field plates 603a, 603b from a gate metal 603 by splitting the gate metal 603 into one or more parts; and/or forming one or more field plates 222a, 222b from an Ohmic metal of the second electrode 122 of a unit cell 120b of the second type representing a source electrode by splitting the Ohmic metal into one or more parts, e.g., as described above with respect to FIGS. 6a to 6d.

The method 800 may further comprise: forming a dielectric layer above the top surface 111 of the semiconductor device, in particular the top surface of the die layer 110, and one or more additional metal layers on top of the dielectric layer, the one or more additional metal layers acting as one or more additional field plates, e.g., as described above with respect to FIGS. 5a to 6d.

These additional metal layers can also be split. They can also be connected to other electrodes through vias in the cross section of the device or outside the cross section.

While a particular feature or aspect of the present disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise.” Also, the terms “exemplary,” “for example,” and “e.g.” are merely meant as an example, rather than the best or optimal. The terms “coupled” and “connected,” along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the disclosure. This application is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the disclosure beyond those described herein. While the disclosure has been described with reference to one or more particular embodiments, those skilled in the art recognize that many changes may be made thereto without departing from the scope of the disclosure. It is therefore to be understood that within the scope of the appended claims and their equivalents, the present disclosure may be practiced otherwise than as specifically described herein.

What is claimed is:

1. A semiconductor device, comprising:
a plurality of unit cells arranged side-by-side across a top surface of the semiconductor device, wherein the plurality of unit cells are of a first type or a second type, each unit cell of the first type comprises a first electrode, a second electrode, and a third electrode formed at the top surface of the semiconductor device;
wherein the second electrode is arranged to enclose the first electrode;
wherein each of the first and second electrodes is arranged to enclose the third electrode;
wherein the unit cells of the first type form high electron mobility transistor (HEMT) cells; and
wherein the unit cells of the second type form Schottky Barrier Diode (SBD) cells.

2. The semiconductor device of claim 1,
wherein each unit cell of the second type comprises a first electrode and a second electrode formed at the top surface of the semiconductor device;
wherein the first electrode of the unit cell of the second type is arranged to enclose the second electrode of the unit cell of the second type.

3. The semiconductor device of claim 2,
wherein the first electrode of the unit cell of the second type forms an Anode of the SBD cell and the second electrode of the unit cell of the second type forms a Cathode of the SBD cell.

4. The semiconductor device of claim 3,
wherein one or more unit cells of the second type comprise a third electrode formed at the top surface of the semiconductor device;
wherein the third electrode is arranged to enclose the first electrode of the unit cell of the second type and the second electrode of the unit cell of the second type, or
wherein the third electrode is arranged to be enclosed by the first electrode of the unit cell of the second type and the second electrode of the unit cell of the second type.

5. The semiconductor device of claim 4,
wherein the third electrode of the one or more unit cells of the second type forms a Source electrode.

6. The semiconductor device of claim 5,
wherein the Source electrode is electrically shorted to the Anode of the SBD cell.

7. The semiconductor device of claim 3,
wherein the first electrode of the unit cell of the second type forms a closed geometrical contour around the second electrode of the unit cell of the second type.

8. The semiconductor device of claim 7,
wherein the closed geometrical contour is symmetrical about one or more directions along the top surface of the semiconductor device, and
wherein the closed geometrical contour has at least one sharp corner, at least one rounded corner, and/or at least one cut corner.

9. The semiconductor device of claim 7,
wherein at least one of the first electrode, the second electrode and the third electrode of the unit cell of the second type is stretched in a direction along the top surface of a die layer.

10. The semiconductor device of claim 3, comprising:
a Gallium Nitride (GaN) layer and an Aluminum Gallium Nitride (AlGaN) layer formed on top of the GaN layer,
wherein any of the electrodes of the SBD cell forms a field plate above the AlGaN layer.

11. The semiconductor device of claim 10,
wherein the first electrode of the unit cell corresponding to the Anode of the SBD cell is laying on top of the AlGaN layer, or
wherein the first electrode of the unit cell corresponding to the Anode of the SBD cell is laying on top of a dielectric deposited on the AlGaN layer.

12. The semiconductor device of claim 10,
wherein the first electrode of the unit cell extends into the AlGaN layer without reaching the GaN layer.

13. The semiconductor device of claim 10,
wherein the first electrode of the unit cell extends into the AlGaN layer up to the GaN layer without extending into the GaN layer.

14. The semiconductor device of claim 10,
wherein the first electrode of the unit cell extends into the AlGaN layer and further extends into the GaN layer.

15. The semiconductor device of claim 10,
wherein field plates of the first electrode of the unit cell corresponding to the Anode of the SBD cell, the second electrode of the unit cell corresponding to the Cathode of the SBD cell and a gate metal of the SBD cell are arranged at different heights above the top surface of the semiconductor device.

16. The semiconductor device of claim 1,
wherein one or more SBD cells are inserted into a block of the HEMT cells;
wherein a number of the one or more SBD cells and a number of the HEMT cells of the semiconductor device is based on a ratio between forward conduction and reverse conduction of the semiconductor device.

17. The semiconductor device of claim 1,
wherein one or more unit cells of the first type and the second type are arranged in a staggered pattern across the top surface of the semiconductor device without forming areas of the semiconductor device in between the unit cells or at least subareas thereof which are not occupied by unit cells, or
wherein the one or more unit cells of the first type and the second type are aligned with respect to each other such that areas of the semiconductor device in between the unit cells or at least subareas thereof are formed which are not occupied by the unit cells.

18. The semiconductor device of claim 1, comprising:
one or more first metal tracks for routing Drain currents of the HEMT cells and Cathode currents of the SBD cells.

19. The semiconductor device of claim 18, comprising:
one or more second metal tracks for routing Source currents of the HEMT cells and Anode currents of the SBD cells,
wherein a thickness of the one or more second metal tracks is greater in an area above the SBD cells than in an area above the HEMT cells for shortcutting a Source electrode of a respective SBD cell with an Anode of the SBD cell.

20. A method for manufacturing a semiconductor device, the method comprising:
forming a plurality of unit cells arranged side-by-side across a top surface of the semiconductor device, wherein the plurality of unit cells are of a first type or a second type; and
forming for each unit cell of the first type a first electrode, a second electrode, and a third electrode at the top surface of the semiconductor device such that the second electrode is arranged to enclose the first electrode, and wherein each of the first and second electrodes is arranged to enclose the third electrode,
wherein the unit cells of the first type form high electron mobility transistor (HEMT) cells, and
wherein the unit cells of the second type form Schottky Barrier Diode (SBD) cells.

21. The method of claim 20, comprising:
forming for each unit cell of the second type a first electrode and a second electrode at the top surface of the semiconductor device such that the first electrode is arranged to enclose the second electrode; and
forming for each unit cell of the second type a third electrode at the top surface of the semiconductor device.

22. The method of claim 21,
wherein a gate metal of a unit cell of the second type is formed before the first electrode of a unit cell of the second type representing an Anode electrode is formed, or
wherein the first electrode of a unit cell of the second type representing an Anode electrode is formed before a gate metal of a unit cell of the second type is formed.

23. The method of claim 22, comprising:
forming one or more field plates from the gate metal by splitting the gate metal into one or more parts; and/or
forming one or more field plates from an Ohmic metal of the
second electrode of a unit cell of the second type representing a source electrode by splitting the Ohmic metal into one or more parts.

24. The method of claim 23, comprising:
forming a dielectric layer above the top surface of the semiconductor device and one or more additional metal layers on top of the dielectric layer, the one or more additional metal layers acting as one or more additional field plates.
